(19) United States
(12) Patent Application Publication
(10) Pub. No.: US 2026/0119746 A1
(43) Pub. Date: Apr. 30, 2026

(54) METHOD OF FUNCTION SIMULATION FOR ELECTRONIC DEVICE AND FUNCTIONAL SIMULATION SYSTEM USING THE SAME

(71) Applicant: HTC Corporation, Taoyuan City (TW)

(72) Inventors: Chen-Yu Chuang, Taoyuan City (TW); Dong Chang Lin, Taoyuan City (TW); Fang Yu Cheng, Taoyuan City (TW)

(73) Assignee: HTC Corporation, Taoyuan City (TW)

(21) Appl. No.: 19/055,465

(22) Filed: Feb. 17, 2025

Related U.S. Application Data
(60) Provisional application No. 63/711,704, filed on Oct. 25, 2024.
(60) Provisional application No. 63/718,741, filed on Nov. 11, 2024.

(51) Int. Cl. G06F 30/23; G06T 7/10; G06T 17/20

(52) U.S. Cl. CPC G06F 30/23; G06T 7/10; G06T 17/20

(57) ABSTRACT

A method of function simulation for electronic devices and a functional simulation system using the same method are provided. The method includes: obtaining a computer aided design file of the electronic device, wherein the computer aided design file includes a three-dimensional object; segmenting a first face of the three-dimensional object into a plurality of first meshes; identifying the three-dimensional object as a functional component according to the plurality of first meshes; and outputting information of the functional component.

### CROSS-REFERENCE TO RELATED APPLICATION

This application claims the priority benefit of U.S. provisional application Ser. No. 63/711,704, filed on Oct. 25, 2024 and U.S. provisional application Ser. No. 63/718,741, filed on Nov. 11, 2024. The entirety of each of the above-mentioned patent applications is hereby incorporated by reference herein and made a part of this specification.

### BACKGROUND

### Technical Field

The disclosure is related to image processing technology, and particularly related to a method of function simulation for electronic devices and a functional simulation system using the same method.

### Description of Related Art

Functional components such as cameras, light-emitting diodes (LEDs), inertial measurement units (IMUs), structured light, or time of flight (TOF) sensors, as well as mechanical structures, must be strategically positioned to meet system requirements for optimal product performance. For example, achieving effective tracking in extended reality (XR) devices requires precise placement of cameras and structured light, while mobile phones demand efficient spatial arrangements of chips, camera modules, and batteries to minimize device size.

A primary technical problem lies in the translation of design elements into mechanical design language and functional simulation parameters. Existing workflows often need to perform manual coordinate system origin alignment and coordinate axis conversion in order to synchronize with the posture standard required by the functional simulation evaluation, which cause a lot of processes that cannot be automated, and increase manpower consumption, budget consumption, human factors, learning thresholds, and error rates.

One approach to resolve the problems mentioned above is generating positional and orientation data directly from mechanical design software. However, differences in mechanical designer outputs and the need for manual axis conversions create inconsistencies and high communication costs. Another approach is using third-party software to perform the basic simulation for the mechanical design file beforehand. While this reduces manual intervention, it imposes environmental limitations, budget constraints, and requires design operators to have prerequisite knowledge of functional simulation, further complicating communication and workflow integration.

### SUMMARY

The disclosure is directed to a functional simulation system and a method of function simulation for electronic devices.

The present invention is directed to a functional simulation system for an electronic device, including a transceiver and a processor. The processor is coupled to the transceiver, wherein the processor is configured to: obtain a computer aided design file of the electronic device through the transceiver, wherein the computer aided design file includes a three-dimensional object; segment a first face of the three-dimensional object into a plurality of first meshes; identify the three-dimensional object as a functional component according to the plurality of first meshes; and output information of the functional component through the transceiver.

In one embodiment of the present invention, the processor is further configured to: segment a second face of the three-dimensional object into a plurality of second meshes; and identify the three-dimensional object as the functional component according to the plurality of first meshes and the plurality of second meshes.

In one embodiment of the present invention, the processor further identifies the three-dimensional object according to at least one of the following: a center of gravity of the three-dimensional object, a circumcircle of the three-dimensional object; a number of a first set of the plurality of first meshes, wherein each first mesh in the first set corresponds to a normal aligned with a first direction; a total area of the first set; a symmetry in the number of the first set and a number of a second set of the plurality of first meshes corresponding to a second direction; or a number of vertexes of the plurality of first meshes in the first face.

In one embodiment of the present invention, the functional component includes a first position marker.

In one embodiment of the present invention, the processor is further configured to: receive a user command through the transceiver, wherein the user command includes a first yaw angle and a first pitch angle of the three-dimensional object; detect a plurality of position markers on the three-dimensional object based on the first yaw angle and the first pitch angle to generate a first detection result, wherein plurality of position markers include the first position marker; determine a first difference between the first detection result and a first reference detection result corresponding to the first yaw angle and the first pitch angle; and output a first alarm message according to the first difference.

In one embodiment of the present invention, the processor is further configured to: detect the plurality of position markers on the three-dimensional object based on a second yaw angle and a second pitch angle to generate a second detection result, wherein a first offset between the first yaw angle and the second yaw angle is less than a first threshold, and a second offset between the first pitch angle and the second pitch angle is less than a second threshold; input the second detection result into an object tracking algorithm to obtain a tracking score; and output the tracking score.

In one embodiment of the present invention, the processor is further configured to: determine a distance between the first position marker and a second position marker on the three-dimensional object; and in response to the distance being less than a threshold, output an alarm message.

In one embodiment of the present invention, the information includes at least one of an orientation of the functional component, a position of the functional component, or a size of the functional component.

The present invention is directed to a method of function simulation for an electronic device, including: obtaining a computer aided design file of the electronic device, wherein the computer aided design file includes a three-dimensional object; segmenting a first face of the three-dimensional object into a plurality of first meshes; identifying the three-dimensional object as a functional component according to the plurality of first meshes; and outputting information of the functional component.

In one embodiment of the present invention, the step of identifying the three-dimensional object as the functional component according to the plurality of first meshes including: segmenting a second face of the three-dimensional object into a plurality of second meshes; and identifying the three-dimensional object as the functional component according to the plurality of first meshes and the plurality of second meshes.

In one embodiment of the present invention, the three-dimensional object is further identified according to at least one of the following: a center of gravity of the three-dimensional object, a circumcircle of the three-dimensional object; a number of a first set of the plurality of first meshes, wherein each first mesh in the first set corresponds to a normal aligned with a first direction; a total area of the first set; a symmetry in the number of the first set and a number of a second set of the plurality of first meshes corresponding to a second direction; or a number of vertexes of the plurality of first meshes in the first face.

In one embodiment of the present invention, the functional component includes a first position marker.

In one embodiment of the present invention, the method further including: receiving a user command, wherein the user command includes a first yaw angle and a first pitch angle of the three-dimensional object; detecting a plurality of position markers on the three-dimensional object based on the first yaw angle and the first pitch angle to generate a first detection result, wherein the plurality of position markers include the first position marker; determining a first difference between the first detection result and a first reference detection result corresponding to the first yaw angle and the first pitch angle; and outputting a first alarm message according to the first difference.

In one embodiment of the present invention, the method further including: detecting the plurality of position markers on the three-dimensional object based on a second yaw angle and a second pitch angle to generate a second detection result, wherein a first offset between the first yaw angle and the second yaw angle is less than a first threshold, and a second offset between the first pitch angle and the second pitch angle is less than a second threshold; inputting the second detection result into an object tracking algorithm to obtain a tracking score; and outputting the tracking score.

In one embodiment of the present invention, the method further including: detecting a distance between the first position marker and a second position marker on the three-dimensional object; and in response to the distance being less than a threshold, outputting an alarm message.

In one embodiment of the present invention, the information includes at least one of an orientation of the functional component, a position of the functional component, or a size of the functional component.

Based on the above description, the functional simulation system may integrate the mechanical design and function design of an electronic device using the analysis results of computer aided design (CAD) files.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a functional simulation system for an electronic device according to one embodiment of the present invention.

FIG. 2 illustrates a schematic diagram of a three-dimensional (3D) object according to one embodiment of the present invention.

FIG. 3 illustrates a schematic diagram of the functional component according to one embodiment of the present invention.

FIG. 4 illustrates a schematic diagram of the posture of the 3D object according to one embodiment of the present invention.

FIG. 5 illustrates a schematic diagram of a graphical user interface (GUI) according to one embodiment of the present invention.

FIG. 6 illustrates a schematic diagram of the GUI according to one embodiment of the present invention.

FIG. 7 illustrates a flowchart of a method of function simulation for an electronic device according to one embodiment of the present invention.

### DESCRIPTION OF THE EMBODIMENTS

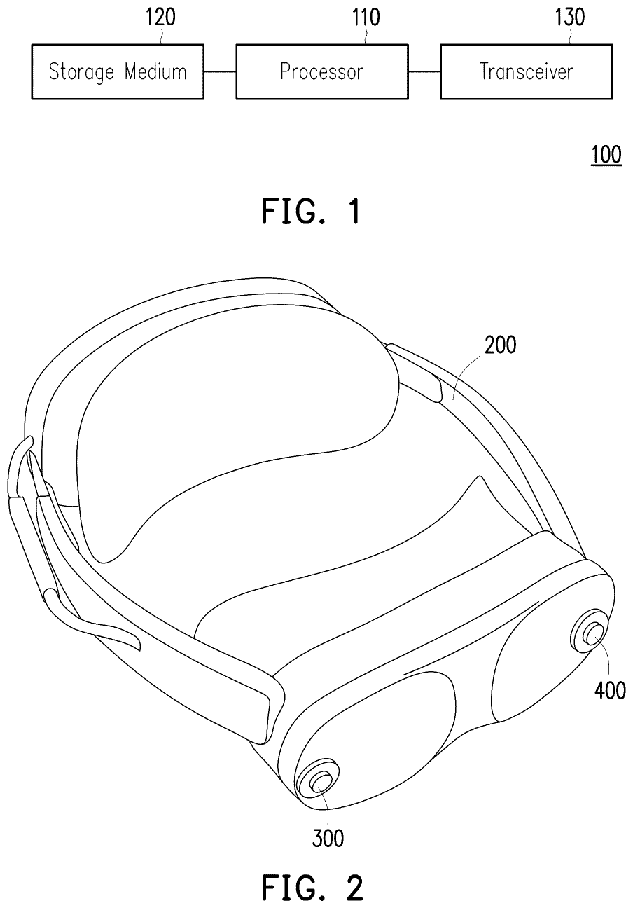

FIG. 1 illustrates a schematic diagram of a functional simulation system 100 for an electronic device according to one embodiment of the present invention. The functional simulation system 100 may include a processor 110, a storage medium 120, and a transceiver 130.

The processor 110 may be, for example, a central processing unit (CPU), or other programmable general purpose or special purpose micro control unit (MCU), a microprocessor, a digital signal processor (DSP), a programmable controller, an application specific integrated circuit (ASIC), a graphics unit (GPU), an arithmetic logic unit (ALU), a complex programmable logic device (CPLD), a field programmable gate array (FPGA), or other similar device or a combination of the above devices. The processor 110 may be coupled to the storage medium 120 and the transceiver 130.

The storage medium 120 may be, for example, any type of fixed or removable random access memory (RAM), a read-only memory (ROM), a flash memory, a hard disk drive (HDD), a solid state drive (SSD) or similar element, or a combination thereof. The storage medium 120 may be a non-transitory computer readable storage medium configured to record a plurality of executable computer programs, modules, or applications to be loaded by the processor 110 to perform the functions of the functional simulation system 100.

The transceiver 130 may be configured to transmit or receive wired/wireless signals. The transceiver 130 may also perform operations such as low noise amplifying, impedance matching, frequency mixing, up or down frequency conversion, filtering amplifying, and so forth. The processor 110 may communicate with other external devices via the transceiver 130. In one embodiment, the processor 110 may obtain one or more CAD files from an external device (e.g., a computer) through the transceiver 130. A CAD file may include illustrations of one or more 3D objects. In one embodiment, the processor 110 may output a GUI through the transceiver 130.

In one embodiment, the 3D object in the CAD file may include a specialized structure representing a functional component. The function component may be an electronic component including but not limited to a sensor, a camera, a camera array, an optical emitter, a LED, an IMU, a TOF sensor, a structured light, or a position maker.

FIG. 2 illustrates a schematic diagram of a 3D object 200 according to one embodiment of the present invention. The 3D object 200 may be a head-mounted display (HMD). The 3D object 200 may include be configured with a 3D object 300 with a specialized structure representing a functional component and a 3D object 400 with a specialized structure representing another functional component. The 3D object 300 (or 400) may be, for example, a camera.

In order to identify whether a 3D object in a CAD file is a functional component, the functional simulation system 100 may segment each face of the 3D object into a plurality of meshes. For example, the functional simulation system 100 may apply a mesh segmentation algorithm to each face of the 3D object. The mesh may be, for example, a triangular mesh or a quad mesh, depending on the algorithm used. The functional simulation system 100 may identify whether the 3D object is a functional component according to the plurality of meshes of each face of the 3D object. The functional simulation system 100 may output information of the identified functional component through the transceiver 130 for user reference. The information may include specification parameters of the identified functional component such as an orientation (e.g., yaw, pitch, or roll), a position (e.g., coordinate), or a size.

In one embodiment, the functional simulation system 100 may update the design of the 3D object in the CAD file according to the identified functional component. For example, after a camera (e.g., 3D object 300 or 400) on a HMD (e.g., 3D object 200) is identified by the functional simulation system 100, the functional simulation system 100 may adjust the position of the camera if the functional simulation system 100 finds out that the optical axis of the camera is blocked by a mechanical structure of the HMD. After the adjustment, the optical axis of the camera will no longer be blocked. Accordingly, the design of the 3D object in the CAD file can be updated.

In one embodiment, the functional simulation system 100 may identify a 3D object according to the following parameters: a center of gravity of the 3D object; a circumcircle of the 3D object; the number of a set of meshes of the 3D object, wherein each mesh in the set may correspond to a normal aligned with a specific direction; a total area of the set of meshes of the 3D object; a symmetry in the number of multiple sets of meshes of the 3D object (e.g., the number of meshes in a set with normals aligned with a first direction and the number of meshes in another set with normals aligned with a second direction); or the number of vertexes of the meshes in each face of the 3D object. For example, if the 3D object has some guide angles or holes, the center of gravity may move. Therefore, the functional simulation system 100 may identify the 3D object based on the position of the center of gravity.

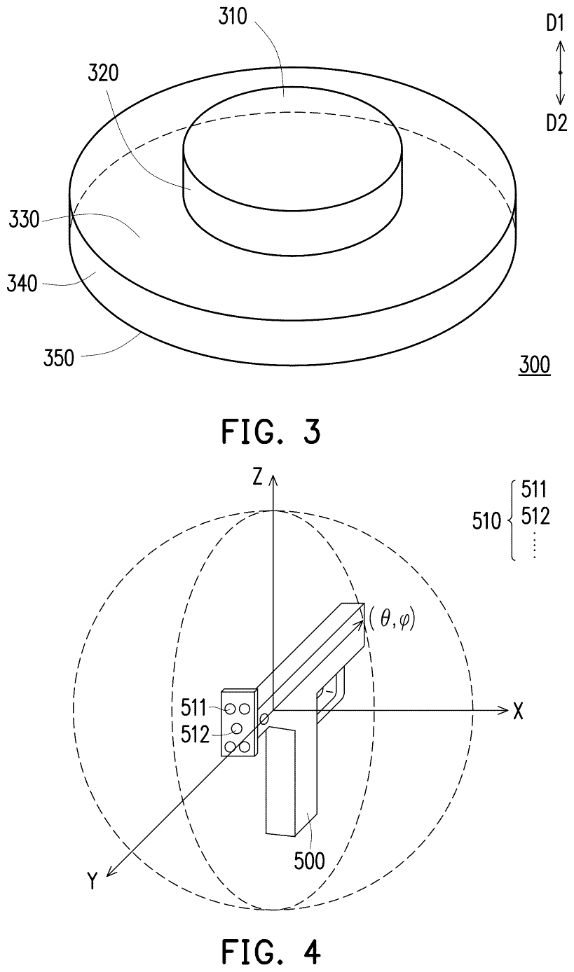

FIG. 3 illustrates a schematic diagram of the functional component 300 according to one embodiment of the present invention. The functional component 300 may include 5 faces (i.e., regions enclosed by solid lines) such as face 310, face 320, face 330, face 340, and face 350. The functional simulation system 100 may segment each face into a plurality of meshes, and may identify the functional component 300 according to the meshes of each face of the functional component 300.

For example, the functional simulation system 100 may apply a mesh segmentation algorithm to the face 310 to segment the face 310 into n meshes and each mesh may have a normal that is aligned with the direction D1, where n is a positive integer. On the other hand, the functional simulation system 100 may apply the mesh segmentation algorithm to the face 350 to segment the face 350 into m meshes and each mesh have a normal that is aligned with the direction D2, where m is a positive integer. Since the face 310 is a circle with a higher curvature and the face 350 is a circle with a lower curvature, the integer n may be greater than the integer m based on the result of applying the mesh segmentation algorithm.

Assume that the face 330 is segmented into k meshes, where k is a positive integer. The functional simulation system 100 may determine that the number of meshes corresponding to normals aligned with the direction D1 is n+k and the number of meshes corresponding to normals aligned with the direction D2 is m. The functional simulation system 100 may identify the 3D object 300 based on n+k being greater than m. That is, the functional simulation system 100 may identify the 3D object 300 based on the symmetry in the number of multiple sets of meshes of the 3D object 300.

In order to design an object that can be tracked by applying object tracking algorithm on an image, one or more position marker (e.g., LED) should be placed on the object. The more complex the structure of the object, the more position markers may be required.

FIG. 4 illustrates a schematic diagram of the posture of the 3D object 500 according to one embodiment of the present invention. The functional simulation system 100 may identify one or more functional components on the 3D object 500, such as a position marker array (or LED array) 510, wherein the position marker array 510 may include position marker 511 and position marker 512.

To determine whether the position marker array 510 is properly placed to enable a specific posture of the 3D object 500 to be easily tracked by an object tracking algorithm, the functional simulation system 100 may receive a user command through the transceiver 130, wherein the user command may include yaw angle θ and a pitch angle φ of the 3D object 500. The functional simulation system 100 may output the information related to the yaw angle θ and the pitch angle φ of the 3D object 500 through a GUI.

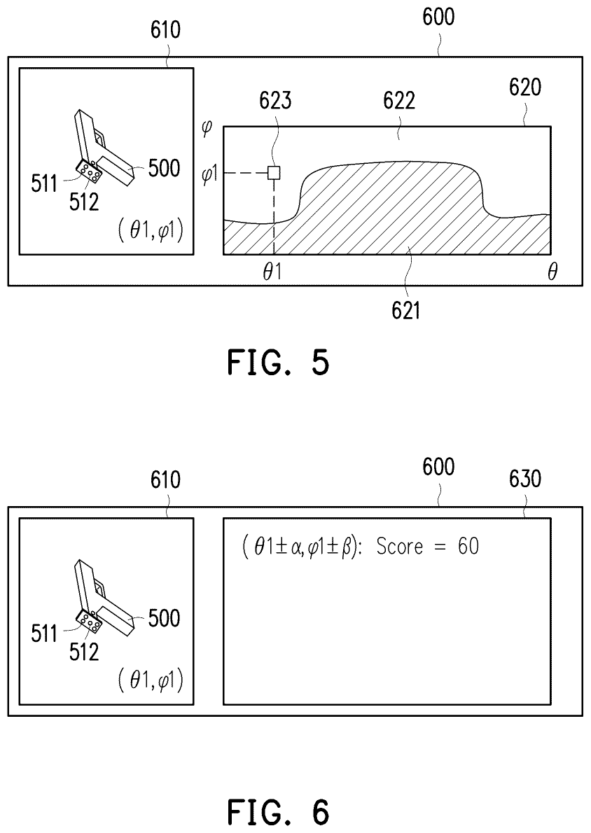

FIG. 5 illustrates a schematic diagram of a GUI 600 according to one embodiment of the present invention. The GUI 600 may include region 610 and region 620. The functional simulation system 100 may store reference detection results corresponding to each yaw angle θ and pitch angle φ of the 3D object 500. Assume that the functional simulation system 100 receive a user command indicating a yaw angle θ1 and a pitch angle φ1 of the 3D object 500, the functional simulation system 100 may display the 3D object 500 in the region 610 based on the yaw angle θ1 and the pitch angle φ1. The functional simulation system 100 may detect one or more position markers (e.g., 511 or 512) on the displayed image corresponding to (θ1, φ1) to generate a detection result corresponding to (θ1, φ1). The functional simulation system 100 may determine a difference between the detection result corresponding to (θ1, φ1) and the reference detection result corresponding to (θ1, φ1) and may determine whether to output an alarm message according to the difference. For example, if the difference between the detection result corresponding to (θ1, φ1) and the reference detection result corresponding to (θ1, φ1) is greater than a threshold, the functional simulation system 100 may determine that the position marker array 510 is not placed properly and may output the alarm message accordingly. Otherwise, if the difference is less than or equal to the threshold, the functional simulation system 100 may determine that the position marker array 510 is placed properly and may determine not to output the alarm message. The determined result can be represented as a tracking score. In one embodiment, the difference mentioned above can be calculated by using an object tracking algorithm.

The region 620 of the GUI 600 may display a diagram indicating whether a specific posture of the functional simulation system 100 can be properly tracked according to the current placement of the position marker array 500. For example, the region 620 may be divided into a non-critical region 621 and a critical region 622. The posture belonging to the non-critical region 621 is less important for object tracking. Therefore, the analysis for the posture belonging to the non-critical region 621 can therefore be excluded from analysis. On the other hand, the posture belonging to the critical region 622 is important for the object tracking. The functional simulation system 100 may evaluate whether the current placement of the position marker array 500 is acceptable for the posture belonging to the critical region 622. For example, if the functional simulation system 100 determines that the current placement of the position marker array 500 is acceptable for the posture (θ1, φ1), the functional simulation system 100 may render the subregion 623 in the critical region 622 as green, wherein the subregion 623 is corresponded to the posture (θ1, φ1). Otherwise, if the functional simulation system 100 determines that the current placement of the position marker array 500 is not acceptable for the posture (θ1, φ1), the functional simulation system 100 may render the subregion 623 as black.

FIG. 6 illustrates a schematic diagram of the GUI 600 according to one embodiment of the present invention. The GUI 600 may include a region 630 to display the tracking score for the posture (θ1, φ1) of the 3D object 500. Specifically, after receiving a user command indicating the posture (θ1, φ1), the functional simulation system 100 may detect one or more position markers on the 3D object 500 based on a range of postures (θ1±α, φ1±β) to generate corresponding detection results, where α and β are offsets less than a yaw angle threshold and a pitch angle threshold, respectively. The functional simulation system 100 may input the detection results (e.g., for the posture (θ1, φ1) and nearby postures (θ1±α, φ1±β)) into an object tracking algorithm to calculate a tracking score for the posture (θ1, φ1). This tracking score may be displayed in region 630 of the GUI 600. If the tracking score for the posture (θ1, φ1) exceeds a default value, the posture (θ1, φ1) is unlikely to experience tracking failure due to slight movements or vibrations.

In one embodiment, the functional simulation system 100 may determine a distance between two (or more) position markers (e.g., 511 or 512) on a 3D object (e.g., 500). If the distance is less than a threshold, the position markers may interfere with each other or provide minimal benefits for object tracking. Accordingly, the functional simulation system 100 may output an alarm message through the GIO 600.

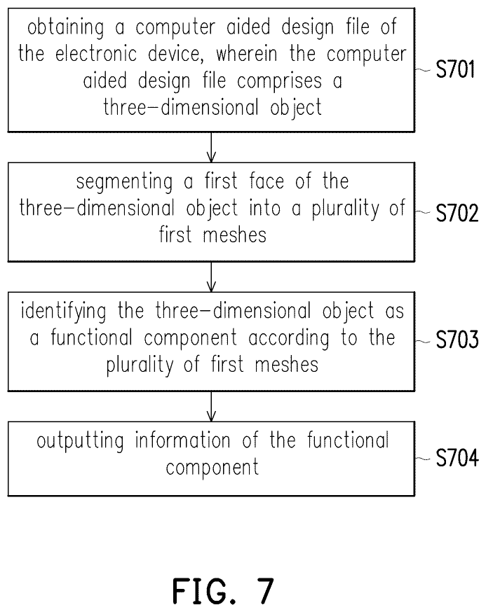

FIG. 7 illustrates a flowchart of a method of function simulation for an electronic device according to one embodiment of the present invention, wherein the method may be implemented by the functional simulation system 100 as shown in FIG. 1. In step S701, obtaining a computer aided design file of the electronic device, wherein the computer aided design file comprises a three-dimensional object. In step S702, segmenting a first face of the three-dimensional object into a plurality of first meshes. In step S703, identifying the three-dimensional object as a functional component according to the plurality of first meshes. In step S704, outputting information of the functional component.

In summary, the functional simulation system of the present invention may segment each face of the 3D object in the CAD file to obtain a plurality of meshes of each face. Since 3D objects with different shapes may result in different segmentation outcomes, the functional simulation system may identify a 3D object based on its segmentation outcomes. To perform object tracking (or motion capture) of a 3D object, the placement of the position markers must be precise. For a specific posture of the 3D object, the simulation system may evaluate whether the current placement of the position markers for that posture is acceptable, ensuring that slight movements or vibrations of the 3D object do not lead to tracking failures.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A functional simulation system for an electronic device, comprising:
a transceiver; and
a processor, coupled to the transceiver, wherein the processor is configured to:
obtain a computer aided design file of the electronic device through the transceiver, wherein the computer aided design file comprises a three-dimensional object;
segment a first face of the three-dimensional object into a plurality of first meshes;
identify the three-dimensional object as a functional component according to the plurality of first meshes; and
output information of the functional component through the transceiver.

2. The functional simulation system according to claim 1, wherein the processor is further configured to:
segment a second face of the three-dimensional object into a plurality of second meshes; and
identify the three-dimensional object as the functional component according to the plurality of first meshes and the plurality of second meshes.

3. The functional simulation system according to claim 1, wherein the processor further identifies the three-dimensional object according to at least one of the following: a center of gravity of the three-dimensional object, a circumcircle of the three-dimensional object; a number of a first set of the plurality of first meshes, wherein each first mesh in the first set corresponds to a normal aligned with a first direction; a total area of the first set; a symmetry in the number of the first set and a number of a second set of the plurality of first meshes corresponding to a second direction; or a number of vertexes of the plurality of first meshes in the first face.

4. The functional simulation system according to claim 1, wherein the functional component comprises a first position marker.

5. The functional simulation system according to claim 4, wherein the processor is further configured to:
receive a user command through the transceiver, wherein the user command comprises a first yaw angle and a first pitch angle of the three-dimensional object;
detect a plurality of position markers on the three-dimensional object based on the first yaw angle and the first pitch angle to generate a first detection result, wherein plurality of position markers comprise the first position marker;
determine a first difference between the first detection result and a first reference detection result corresponding to the first yaw angle and the first pitch angle; and
output a first alarm message according to the first difference.

6. The functional simulation system according to claim 5, wherein the processor is further configured to:
detect the plurality of position markers on the three-dimensional object based on a second yaw angle and a second pitch angle to generate a second detection result, wherein a first offset between the first yaw angle and the second yaw angle is less than a first threshold, and a second offset between the first pitch angle and the second pitch angle is less than a second threshold;
input the second detection result into an object tracking algorithm to obtain a tracking score; and
output the tracking score.

7. The functional simulation system according to claim 4, wherein the processor is further configured to:
determine a distance between the first position marker and a second position marker on the three-dimensional object; and
in response to the distance being less than a threshold, output an alarm message.

8. The functional simulation system according to claim 1, wherein the information comprises at least one of an orientation of the functional component, a position of the functional component, or a size of the functional component.

9. A method of function simulation for an electronic device, comprising:
obtaining a computer aided design file of the electronic device, wherein the computer aided design file comprises a three-dimensional object;
segmenting a first face of the three-dimensional object into a plurality of first meshes;
identifying the three-dimensional object as a functional component according to the plurality of first meshes; and
outputting information of the functional component.

10. The method according to claim 9, wherein the step of identifying the three-dimensional object as the functional component according to the plurality of first meshes comprising:
segmenting a second face of the three-dimensional object into a plurality of second meshes; and
identifying the three-dimensional object as the functional component according to the plurality of first meshes and the plurality of second meshes.

11. The method according to claim 9, wherein the three-dimensional object is further identified according to at least one of the following: a center of gravity of the three-dimensional object, a circumcircle of the three-dimensional object; a number of a first set of the plurality of first meshes, wherein each first mesh in the first set corresponds to a normal aligned with a first direction; a total area of the first set; a symmetry in the number of the first set and a number of a second set of the plurality of first meshes corresponding to a second direction; or a number of vertexes of the plurality of first meshes in the first face.

12. The method according to claim 9, wherein the functional component comprises a first position marker.

13. The method according to claim 12, further comprising:
receiving a user command, wherein the user command comprises a first yaw angle and a first pitch angle of the three-dimensional object;
detecting a plurality of position markers on the three-dimensional object based on the first yaw angle and the first pitch angle to generate a first detection result, wherein the plurality of position markers comprise the first position marker;
determining a first difference between the first detection result and a first reference detection result corresponding to the first yaw angle and the first pitch angle; and
outputting a first alarm message according to the first difference.

14. The method according to claim 13, further comprising:
detecting the plurality of position markers on the three-dimensional object based on a second yaw angle and a second pitch angle to generate a second detection result, wherein a first offset between the first yaw angle and the second yaw angle is less than a first threshold, and a second offset between the first pitch angle and the second pitch angle is less than a second threshold;
inputting the second detection result into an object tracking algorithm to obtain a tracking score; and
outputting the tracking score.

15. The method according to claim 12, further comprising:
detecting a distance between the first position marker and a second position marker on the three-dimensional object; and
in response to the distance being less than a threshold, outputting an alarm message.

16. The method according to claim 9, wherein the information comprises at least one of an orientation of the functional component, a position of the functional component, or a size of the functional component.
